(19) United States
(12) Patent Application Publication
(10) Pub. No.: US 2012/0288422 A1
(43) Pub. Date: Nov. 15, 2012

(54) GLASS MICRO FLUIDIC DEVICE

(75) Inventor: Edvard KALVESTEN, Hagersten (SE)

(73) Assignee: SILEX MICROSYSTEMS AB, JARFALLA (SE)

(21) Appl. No.: 13/469,377

(22) Filed: May 11, 2012

(30) Foreign Application Priority Data
May 12, 2011 (SE) 1150429-7

(51) Int. Cl. B81B 1/00; B32B 3/20; C03B 23/24

(52) U.S. Cl. 422/502; 65/42; 428/166

(57) ABSTRACT

A method of making a microfluidic device, includes: providing an optically transparent bottom substrate and an optically transparent top substrate, each made of glass. Recesses are made in the top substrate and the top and bottom substrates are bonded together. Then, material is removed from the top substrate to expose the recesses, and a lid is attached to the top substrate so as to cover the recesses whereby channels are formed. At least that surface of the lid facing towards the recesses in the top substrate has a surface roughness of <5 nm, preferably <2 nm. A microfluidic device, including a body of an optically transparent material, and at least one channel extending inside the body, the channels having a bottom surface, a top surface and side walls is also described. The top and bottom surfaces both exhibit surface a roughness <5 nm, preferably <2 nm.

The present invention relates to improvements in microfluidic devices made from glass.

### BACKGROUND OF THE INVENTION

So called microfluidic devices are used extensively in analytic and preparative procedures i.a. in the life sciences. These devices are commonly made from glass materials. In particular they are provided with microfluidic channels in which reagents and/or analytes are transported. These channels are made in the glass materials by physical machining processes such as drilling or etching to provide grooves or recesses. The substrate in which the channels are made are then bonded to a flat substrate to provide a finished device having closed channels. It is impossible to make channels having perfectly flat bottom surfaces using these methods.

A process of this kind is disclosed in an article by Tang et al, “A single-mask substrate transfer technique for the fabrication of high-aspect-ratio micromachined Structures” in J. Micromech. Microeng. 17 (2007) 1575-1582, incorporated herein in its entirety.

Tang et al. uses KOH to open up the channels in the silicon o make the adjacent surfaces planar (to make possible bonding of the lid with the I/O connections).

In an article by Kutchoukov et al “Fabrication of nanofluidic devices . . . ” in Sensors and Actuators A 114 (2004) 521-527 there is presented a technology for fabrication of nanochannels created in glass with which bio-analysis can be performed in combination with fluorescence microscopy. The technology is based on a glass-to-glass anodic bonding process. In the bonding process, an intermediate layer (thin insulating film) is deposited on one of the two glass wafers. The channel is then defined, with one or two photo-patterning steps, in the intermediate layer. Here, a 33 nm thick amorphous silicon layer deposited by low-pressure chemical vapor deposition (LPCVD) is used as an intermediate layer.

It would be desirable to provide microfluidic devices in which both the top and bottom surfaces of the channels in the finished device are perfectly flat. Thereby it would be possible to use the devices in new analytical applications where reflectivity and transparency are required.

### SUMMARY OF THE INVENTION

The object of the present invention is to provide improved microfluidic devices in which the channels are delimited by perfectly or at least nearly perfectly flat top and bottom surfaces.

This object is achieved with a method as defined in claim 1. In a further aspect there is provided a microfluidic device, defined in claim 5. Such device comprises a body of an optically transparent material, and at least one channel extending inside said body, said channels having a bottom surface, a top surface and side walls; and is characterized in that the top and bottom surfaces both exhibit surface a roughness <5 nm, preferably <2 nm.

Further scope of applicability of the present invention will become apparent from the detailed description given hereinafter and the accompanying drawings which are given by way of illustration only, and thus not to be considered limiting on the present invention, and wherein

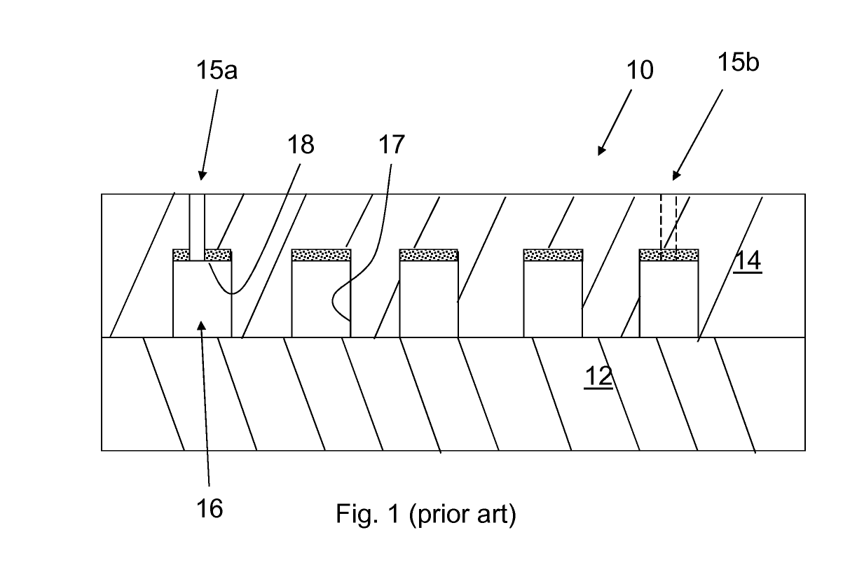

FIG. 1 schematically illustrates a prior art device;

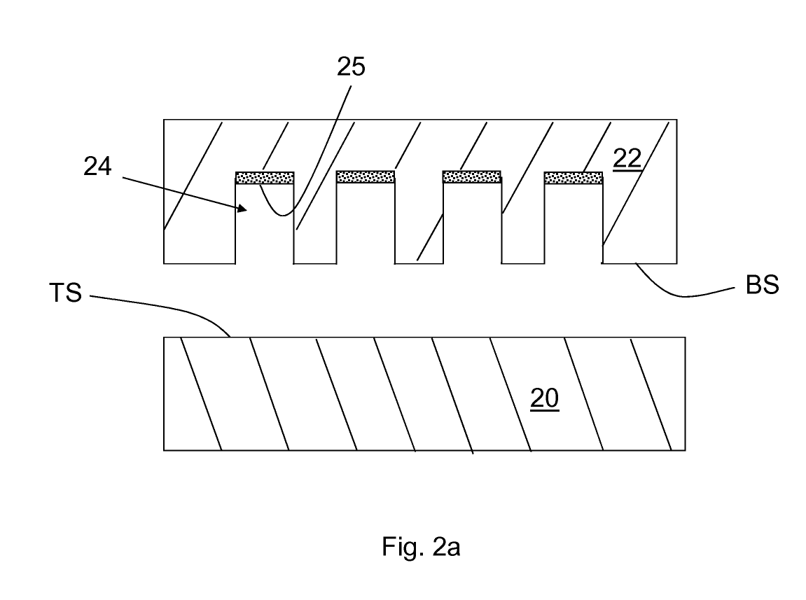

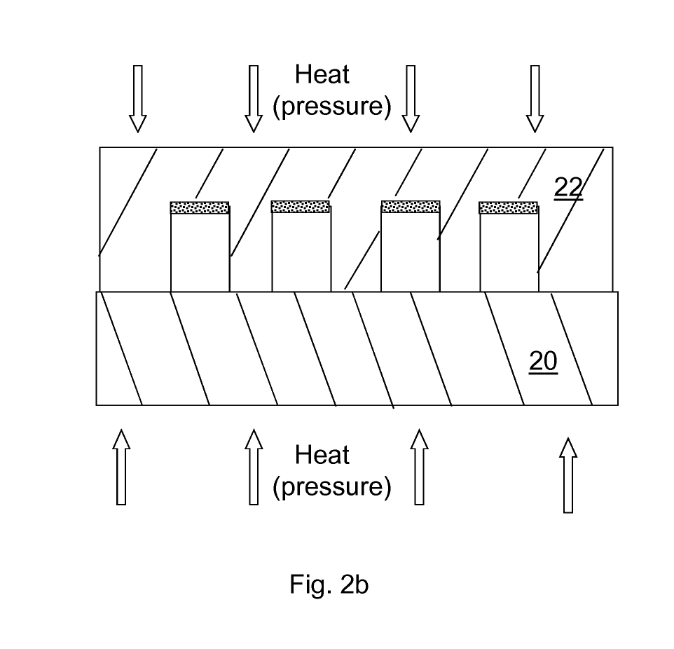

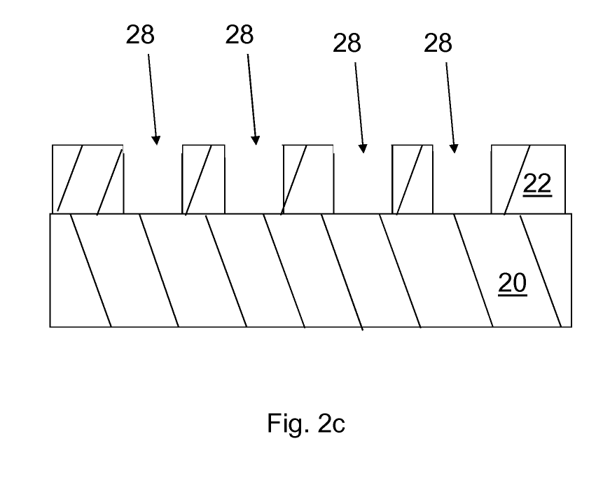

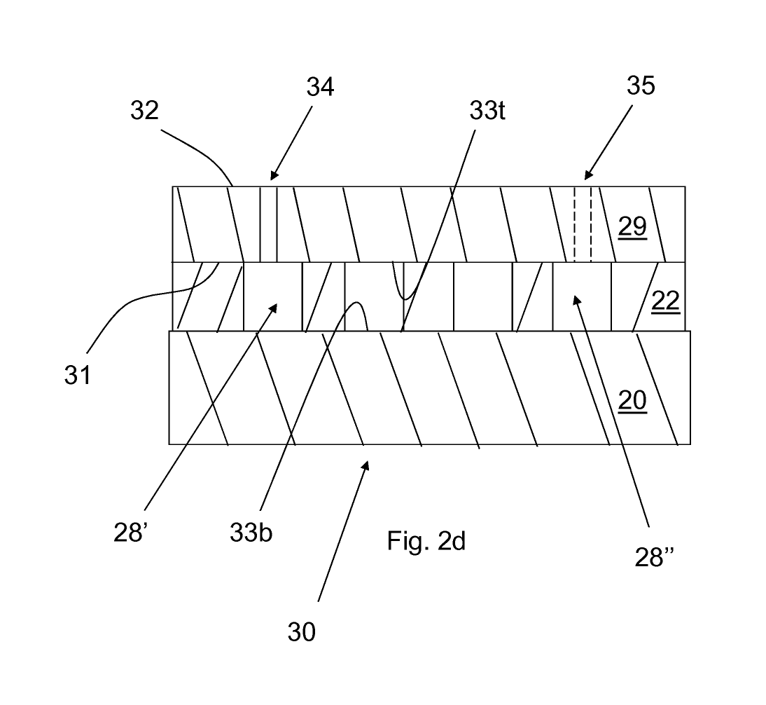

FIG. 2a-d is a manufacturing scheme for making a device according to the invention.

### DETAILED DESCRIPTION OF PREFERRED EMBODIMENTS

For the purpose of this patent application the term “perfectly flat” whenever used should be taken to mean a surface roughness of <5 nm, preferably <2 nm.

A native wafer of an optically transparent material after polishing, and as delivered from most manufacturers would be considered “perfectly flat” for the purposes of this application.

In FIG. 1 a prior art microfluidic device, generally indicated with reference numeral 10, is schematically illustrated.

It comprises a bottom substrate 12 onto which a top substrate 14 is bonded by suitable means well know to the skilled man.

In the top substrate 14 grooves have been made by e.g. drilling, etching or other physical machining processes, five grooves being shown. These grooves form channels 16 when the top and bottom substrates are bonded together as shown.

The side walls 17 of the channels are essentially vertical and the top surface 18 is essentially horizontal (when the device is oriented as shown in the figure).

In order to enable supply of liquid reagents and analytes to the channels there are preferably inlets 15a provided, and there are also outlets 15b for allowing liquid to be removed from the channels.

However, the surface structure of the top surface 18 is not perfect, since the physical processes used for making the grooves making up the channels 16 will excavate material in a relatively coarse manner. This is schematically indicated by showing a region at the top surface 18 in the channels 16 having a dotted structure. The shown region is not to scale, it is merely for illustrative purposes and meant to indicate that the surface is not perfectly flat. In particular the surface roughness of this region will by far exceed the criterion of flatness herein, namely the roughness would be >>5 nm, typically 10-1000 nm.

In accordance with the present invention a device of the type shown in FIG. 1 can be made to have perfectly flat or at least nearly perfectly flat top surfaces in the channel, i.e. a surface roughness of <5 nm, preferably <2 nm, and a method of making such a device will now be described with reference to FIGS. 2a-d.

Thus, as shown in FIG. 2a a bottom substrate 20 and a top substrate 22 are provided. Both are made from an optically transparent material such as glass. Suitable glass materials are low-ion glasses or ion-free glass. Furthermore the substrates both have surface roughnesses <5 nm, preferably <2 nm, at least on the surfaces the will form the interior of the channels in the finished device, i.e. The top surface TS of substrate 20 and the bottom surface BS of the top substrate 22.

In the top substrate 22 there are a plurality (four shown) of grooves or recesses 24 made, e.g. by drilling or etching or any other suitable method. The top and bottom substrates 20, 22 are bonded together by bringing pre-prepared extremely clean and planar surfaces in contact (van der Waals bonding) and then applying heat (indicated by arrows), optionally by applying pressure, as shown in FIG. 2b. After bonding the structure will be essentially the same as the prior art structure shown in FIG. 1, i.e. having channels with “raw” top surfaces 25.

Other methods that can be mentioned are laser ablation and glass-glass anodic bonding. Of course any other suitable methods well known to the skilled man can be used as well.

When the substrates have been bonded together the top substrate 22 is subjected to a machining process so as to remove material for exposing the channels. The machining can be by etching, grinding, polishing or any other suitable method that would yield the same result.

After the machining operation the structure shown in FIG. 2c is obtained, i.e. a bottom substrate 20 on which a top substrate 22 is attached, and wherein there are a plurality of open channels 28 provided.

Then, as shown in FIG. 2d, a third substrate 29, which herein is referred to as a lid 29 is bonded to the combined structure from FIG. 2c, whereby a microfluidic device, generally designated 30, according to the invention is provided. The third substrate 29 is also made of glass and has perfectly flat (as defined herein) opposing surfaces 31, 32. In this way the top surface 33t of the channels 28 will be perfectly flat, and usable in many applications that was not hitherto possible with the prior art devices. Suitably the surface roughness of the top surface 33t in each channel is <5 nm, preferably <2 nm. Thus, the device 30 comprises a body of glass built up from the three substrates 20, 22, 29 within which a plurality of channels 28 extend.

The bottom surface 33b inside the channels 28 will also be perfectly flat, i.e. exhibit a surface roughness of <5 nm, preferably <2 nm, by virtue of the bottom substrate 20 having such roughness at the outset.

In order to enable supply of liquid reagents and analytes to the channels there are preferably inlets 34 provided, and there are also outlets 35 for allowing liquid to be removed from the channels. In FIG. 2d the inlet 34 is shown to exit in the leftmost channel 28′, and the outlet 35, which is shown in dotted lines to indicate that it is located at the farther end of the device (below the plane of the figure), provides an exit from the rightmost channel 28″.

All channels can thus be connected to form a channel system with one inlet and one outlet. Of course there could be provided a plurality of inlets and outlets to individual channels or to several channel systems, the shown embodiment is only a very simple exemplifying embodiment.

These inlets and outlets can be made by etching and/or drilling holes 34 in the lid 29 to get access to the channels 28.

1. A method of making a microfluidic device, comprising the steps of:
providing an optically transparent bottom substrate (20) made of glass;
providing an optically transparent top substrate (22) made of glass;
making recesses (24) in the top substrate;
bonding the top (22) and bottom (20) substrates together;
removing material from the top substrate to expose the recesses (24);
attaching a lid (29) made of glass to the top substrate (22) so as to cover the recesses (24) whereby channels (28) are formed; wherein
at least that surface of the lid and that surface of the bottom substrate that face towards the recesses (24) in the top substrate has a surface roughness of <5 nm, preferably <2 nm.

2. The method as claimed in claim 1, further comprising making inlets and outlets to and from said channels (28).

3. The method as claimed claim 1, wherein the bonding of the substrates is achieved by bringing pre-prepared extremely clean and planar surfaces in contact and then applying heat and optionally pressure

4. The method as claimed in claim 1, wherein the glass is selected from low-ion glasses or ion-free glass.

5. The method as claimed in claim 2, wherein the bonding of the substrates is achieved by bringing pre-prepared extremely clean and planar surfaces in contact and then applying heat and optionally pressure

6. The method as claimed in claim 2, wherein the glass is selected from low-ion glasses or ion-free glass.

7. The method as claimed in claim 3, wherein the glass is selected from low-ion glasses or ion-free glass.

8. A microfluidic device (30), comprising a body (20, 22, 29) made of glass and at least one channel (28) extending inside said body, said channels having a bottom surface (33b), a top surface (33t) and side walls; characterized in that the top (33) and bottom surfaces both exhibit a surface roughness <5 nm, preferably <2 nm.

9. The device as claimed in claim 8, wherein there is provided at least one inlet (34) and one outlet (35) to and from the channels (28′, 28″).

10. The device as claimed in claim 8, comprising a plurality of connected channels forming a channel system with one inlet and one outlet.
